(19) United States
(12) Patent Application Publication
(10) Pub. No.: US 2001/0011908 A1
(43) Pub. Date: Aug. 9, 2001

(54) MULTI-DIMENSIONAL PROGRAMMABLE INPUT SELECTION APPARATUS AND METHOD

(76) Inventor: CHUNG-YUAN SUN, SAN JOSE, CA (US)

Correspondence Address: MCCUTCHEN DOYLE BROWN & ENERSEN, THREE EMBARCADERO CENTER, SAN FRANCISCO, CA, 94111

(21) Appl. No.: 09/250,781

(22) Filed: Feb. 12, 1999

(51) Int. Cl. H03K 19/173

(52) U.S. Cl. 326/46

(57) ABSTRACT

A selection circuit includes a binary selection tree having an output and K number of inputs and a plurality of signal source input circuits coupled to the K number of inputs of the binary selection tree. Each signal source input circuit includes K number of input nodes, a memory cell, and K number of transistors that each have a gate coupled to an output of the memory cell and that are arranged so that each transistor couples a different one of the K number of input nodes to a different one of the K number of inputs of the binary selection tree. A method of selecting from among a plurality of input signals includes arranging the plurality of input signals into J number of groups of input signals; selecting one group from the J number of groups of input signals; coupling each one of the input signals in the selected group to a different one of K number of intermediate nodes; and selecting one of the K number of intermediate nodes with a binary selection tree having K number of inputs.

### BACKGROUND OF THE INVENTION

1. Field of the Invention

The present invention relates to programmable logic devices, and more particularly, to circuits used for selecting a signal from among a number of signal sources.

2. Description of the Related Art

Field programmable logic devices, such as field programmable gate arrays (FPGA), typically use connection transistors to implement programmable connections in a logic array and/or to configure logic functions inside of configurable functional blocks. For example, configurable functional blocks typically include memory cells and connection transistors that may be used to configure logic functions such as addition, subtraction, etc., inside of a field programmable logic device.

A configurable functional block typically needs to select its inputs from a routing resource. FIG. 1 illustrates one conventional selection circuit 16 used for making this selection.

Specifically, the configurable functional block 20 includes an input 22 and an output 24. A selected one of the signal sources 0, 1, 2, 3, . . . n−1, n is connected to the input 22 by turning on the corresponding one of the connection transistors M0, M1, M2, M3, . . . Mn−1, Mn. The connection transistors M0, M1, M2, M3, . . . Mn−1, Mn are turned on and off by the Q output of the corresponding memory cells C0, C1, C2, C3, . . . Cn−1, Cn. In other words, a single one of the n signal sources can be selected as the input 22 of the configurable functional block 20 by programming only one of the n memory cells to have a “1” on its Q output so that only one of the n connection gates is turned on.

With the selection circuit 16 shown in FIG. 1, each of the memory cells controls only one connection transistor. This is a simple solution, but it has the disadvantage that it requires as many memory cells as the number of signal sources. For example, if there are twenty signal sources, twenty memory cells are required. This requires a lot of silicon real estate. On the other hand, the solution shown in FIG. 1 has the advantage that the selected signal source needs to go through only one connection transistor to reach the input 22 of the configurable functional block 20. This means that the selected signal source will go through a path having minimal resistance; in other words, the more transistors through which a selected signal must pass, the more resistive the path will be. Furthermore, the loading for the non-selected signal sources is predictable in that they will each be loaded by only one turned-off transistor.

FIG. 2 illustrates another conventional selection circuit 18 used for selecting a signal source. The selection circuit 18 shown in FIG. 2 is known as a “binary selection tree”. Specifically, transistors M10 and M12 are controlled by the memory cell 30. The Q output of memory cell 30 controls transistor M10, and the Q_B output of memory cell 30 controls transistor M12. This way, either transistor M10 is turned on or transistor M12 is turned on, but both transistors are not turned on at the same time. The path that includes transistor M10 branches out into transistors M14 and M16, and the path that includes transistor M12 branches out into transistors M18 and M20. Transistors M14, M16, M18, and M20 are controlled by the memory cell 32 such that either transistors M14 and M18 are turned on or transistors M16 and M20 are turned on, but all transistors are not turned on at the same time. In a similar manner, transistors M14, M16, M18, and M20 branch out into transistors M22-M36 as shown. Transistors M22-M36 are controlled by the memory cell 34 such that either transistors M22, M26, M30, and M34 are turned on or transistors M24, M28, M32, and M36 are turned on, but all transistors are not turned on at the same time.

During operation, the memory cells 30, 32, 34 are programmed to turn on the transistors that will connect the selected signal source to node 22. For example, if signal source 5 is to be connected to node 22, memory cell 30 is programmed to have a “1” on its Q_B output which turns on transistor M12, memory cell 32 is programmed to have a “1” on its Q output which turns on transistor M18, and memory cell 34 is programmed to have a “1” on its Q_B output which turns on transistor M32. When the memory cells 30, 32, 34 are programmed in this particular manner, signal source 5 is the only one of the signal sources that will be connected to node 22. Specifically, signal sources 0-3 will not be connected because transistor M10 is turned off, signal sources 6-7 will not be connected because transistor M20 is turned off, and signal source 4 will not be connected because transistor M30 is turned off.

With the selection circuit 18 shown in FIG. 2, both the Q and Q_B outputs of the memory cells 30, 32, and 34 are used to control connection transistors, and each of the memory cells 30, 32, and 34 are used to control multiple connection transistors. Thus, the binary selection tree solution has the advantage that the number of required memory cells is greatly reduced from the number of required memory cells in the solution shown in FIG. 1. On the other hand, the binary selection tree solution has the disadvantage that the selected signal source must pass though more than one connection transistor to reach node 22. For example, for the binary selection tree shown in FIG. 2, the selected signal source must pass through three transistors to reach node 22. As mentioned above, passing the signal through several transistors is undesirable because the more transistors through which a selected signal must pass, the more resistive the path will be.

The number of memory cells used in a binary selection tree corresponds to the number of “stages” of the tree. Thus, the binary selection tree shown in FIG. 2 includes three stages and can be used to select from eight signal sources (0-7). Having more stages in the tree allows for selection from a greater number of signal sources, and having fewer stages in the tree allows for selection from a smaller number of signal sources. Specifically, the number of inputs of a binary selection tree is determined by the equation:

Number of Inputs=K=2^{L} (1)

where L is equal to the number of memory cells, or “stages”, used in the tree. For example, a binary selection tree having one memory cell or stage can select from two signal sources, a binary selection tree having two memory cells or stages can select from four signal sources, a binary selection tree having three memory cells or stages can select from eight signal sources (this is the tree shown in FIG. 2), a binary selection tree having four memory cells or stages can select from sixteen signal sources, a binary selection tree having five memory cells or stages can select from thirty-two signal sources, etc. With a binary selection tree, the selected signal must pass through L stages of transistors to reach node 22. Thus, for twenty signal sources, a five stage binary tree must be used which means that the selected signal must pass through five transistors (or stages) to reach node 22.

Another disadvantage of binary selection trees is that the loading of non-selected signal sources can be complicated, particularly with respect to turned-off transistors. Specifically, the non-selected signal sources can have a loading of up to L−1 turned-on transistors. In order to illustrate this, take the example mentioned above with respect to FIG. 2 where signal source 5 is selected. In this scenario, transistors M24 and Ml 4 are turned on. This means that non-selected signal source 1 is passed through transistors M24 and M14, and thus, non-selected signal source 1 is loaded by two turned-on transistors. Because L=3 for the binary selection tree of FIG. 2, non-selected signal source 1 is loaded by L−1 turned-on transistors. As another example, non-selected signal source 3 is loaded by one turned-on transistor, namely, transistor M28.

The loading of non-selected signal sources by turned-off transistors is more difficult to determine. This is because both the Q and Q_B outputs of the memory cells 30, 32, 34 need to be taken into account. Specifically, the non-selected signal sources in a binary selection tree can have a loading of up to L turned-off transistors. Continuing with the example above with respect to FIG. 2 where signal source 5 is selected, transistors M24, M14 will be turned on, and transistors M22, M10, M16 will be turned off. This results in non-selected signal source 1 being loaded by three turned-off transistors, i.e., M22, M10, M16.

FIG. 3 illustrates a conventional CMOS static random access memory (SRAM) cell 36 that may be used for the memory cells shown in FIGS. 1 and 2. Specifically, the cell 36 includes an n-channel pass transistor M40 (or “pass gate”) and two inverters 38, 40 connected back-to-back to form a latch 42. The inverter 38 includes a p-channel transistor M42 and an n-channel transistor M44, and the inverter 40 includes a p-channel transistor M46 and an n-channel transistor M48. Pass transistor M40 is used to connect storage node 44 of the latch 42 to a bit line 48. Pass transistor M40 is activated, or turned on, by a row line signal 50. Storage node 46 forms the Q output of the cell 36, and storage node 44 forms the Q_B output of the cell 36. The memory cells shown in FIG. 1 do not utilize the Q_B output.

Thus, it would be desirable to have an apparatus and method that could be used to select a signal source from among several signal sources that reduces the number of required memory cells from that of the conventional circuit of FIG. 1 and that reduces the number of transistors through which a selected signal must pass from that of the conventional circuit of FIG. 2.

### BRIEF SUMMARY OF THE INVENTION

The present invention provides an apparatus that includes a selection circuit. The selection circuit includes a binary selection tree having an output and K number of inputs and a plurality of signal source input circuits coupled to the K number of inputs of the binary selection tree. Each signal source input circuit includes K number of signal source nodes and is configured to couple each of the K number of signal source nodes to a different one of the K number of inputs of the binary selection tree.

The present invention also provides a selection circuit that includes an output node and K number of intermediate nodes. An output circuit is coupled to the output node and the K number of intermediate nodes. The output circuit is configured to selectively couple the output node to a different one of the K number of intermediate nodes. A plurality of signal source input circuits are coupled to the K number of intermediate nodes. Each signal source input circuit includes K number of input nodes and is configured to couple each of the K number of input nodes to a different one of the K number of intermediate nodes.

The present invention also provides a selection circuit that includes a binary selection tree having an output and K number of inputs and a plurality of signal source input circuits coupled to the K number of inputs of the binary selection tree. Each signal source input circuit includes K number of input nodes, a memory cell, and K number of transistors that each have a gate coupled to an output of the memory cell and that are arranged so that each transistor couples a different one of the K number of input nodes to a different one of the K number of inputs of the binary selection tree.

The present invention also provides a method of selecting from among a plurality of input signals. The method includes arranging the plurality of input signals into J number of groups of input signals; selecting one group from the J number of groups of input signals; coupling each one of the input signals in the selected group to a different one of K number of intermediate nodes; and selecting one of the K number of intermediate nodes with a binary selection tree having K number of inputs.

A better understanding of the features and advantages of the present invention will be obtained by reference to the following detailed description of the invention and accompanying drawings which set forth an illustrative embodiment in which the principles of the invention are utilized.

### BRIEF DESCRIPTION OF THE DRAWINGS

FIG. 1 is a schematic diagram illustrating a conventional signal source selection circuit.

FIG. 2 is a schematic diagram illustrating another conventional signal source selection circuit.

FIG. 3 is a schematic diagram illustrating a conventional memory cell that may be used in the circuits shown in FIGS. 1 and 2.

FIG. 4 is a schematic diagram illustrating a signal source selection circuit in accordance with the present invention.

FIG. 5 is a schematic diagram illustrating another signal source selection circuit in accordance with the present invention.

FIG. 6 is a schematic diagram illustrating another signal source selection circuit in accordance with the present invention.

FIG. 7 is a schematic diagram illustrating another signal source selection circuit in accordance with the present invention.

FIG. 8 is a block diagram illustrating use of a signal source selection circuit of the present invention in a field programmable logic device.

### DETAILED DESCRIPTION OF THE INVENTION

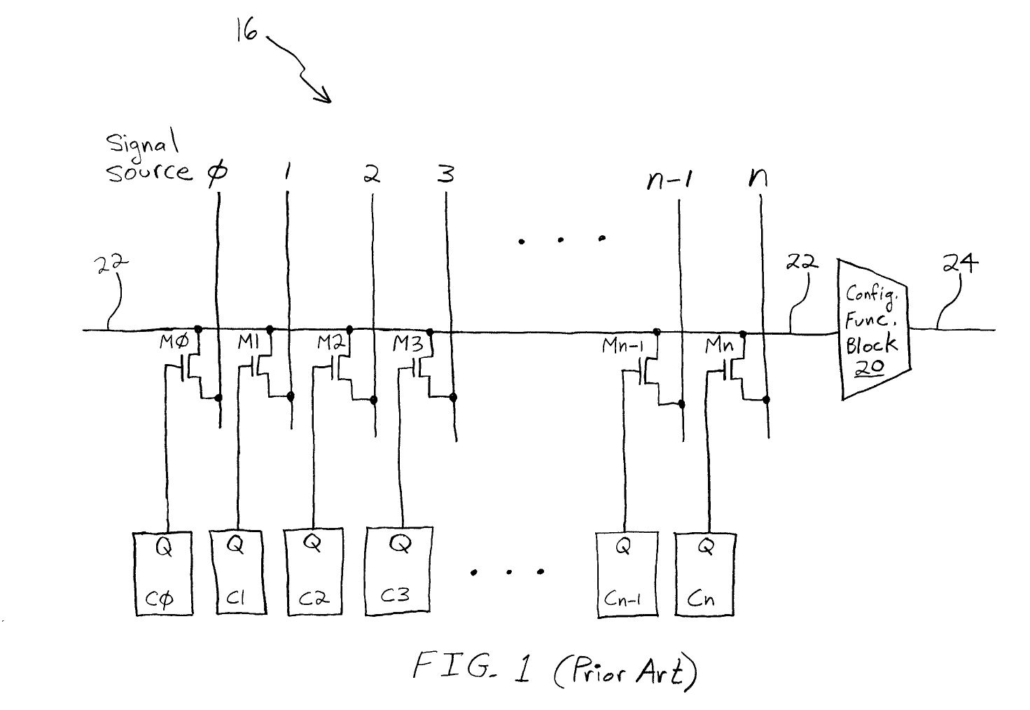

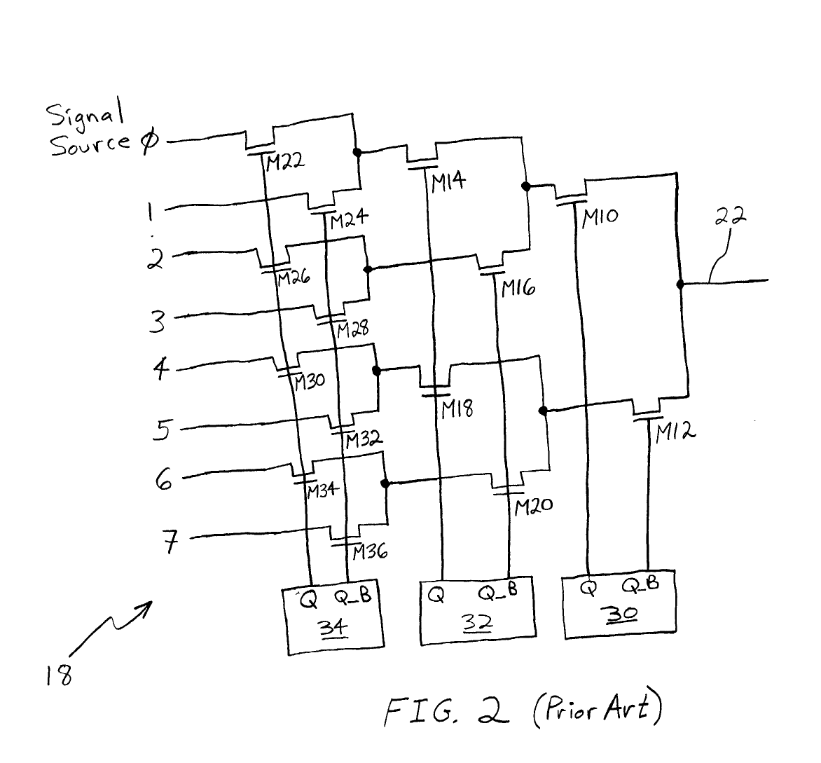

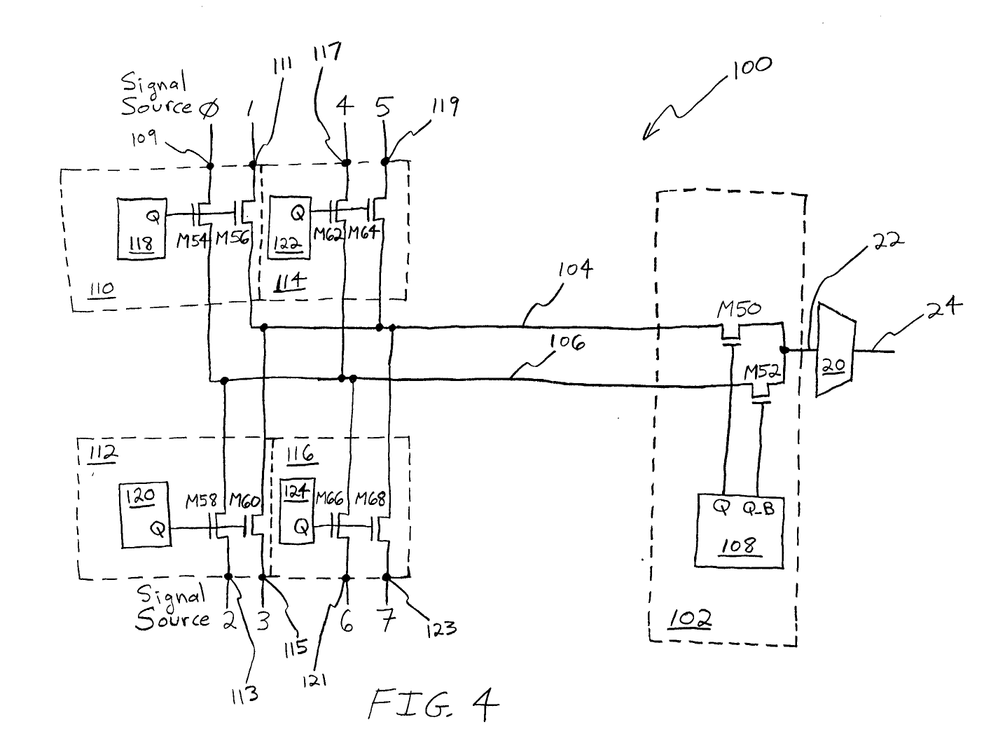

Referring to FIG. 4, there is illustrated a signal source selection circuit 100 in accordance with the present invention. For a given number of signal sources, the selection circuit 100 uses fewer memory cells than the conventional circuit of FIG. 1 and reduces the number of transistors through which a selected signal must pass from that of the conventional circuit of FIG. 2. This means that the selection circuit 100 requires less silicon area than the conventional circuit of FIG. 1 and results in a less resistive path for the selected signal source than the conventional circuit of FIG. 2. In general, the present invention proposes a trade-off of balancing the memory cell usage and the number of connection transistors through which the selected signal source must pass.

The selection circuit 100 uses a binary selection tree 102 to connect to the configurable functional block 20. Specifically, the output of the binary selection tree is connected to the input 22 of the configurable functional block 20. It should be understood that the configurable functional block 20 is not part of the selection circuit 100, but rather, the selection circuit 100 is coupled to the configurable functional block 20. Furthermore, the binary selection tree 102 may also be referred to as an output circuit 102. The number inputs of the binary selection tree 102 depends on the number of stages of the tree according to equation (1) above. The binary selection tree 102 has only one stage, and therefore, the tree 102 has two inputs 104, 106 and uses only one memory cell 108. The inputs 104, 106 of the binary selection tree 102 may also be referred to herein as the intermediate nodes 104, 106. The Q output of memory cell 108 is coupled to the gate of transistor M50, and the Q_B output of memory cell 108 is coupled to the gate of transistor M52. It should be well understood, and it will be demonstrated below, that the signal source selection circuit of the present invention may use a binary selection tree having any number of stages in accordance with the present invention. In general, increasing the number of stages of the binary selection tree 102 will increase the number of signal sources that may be selected, but this will also increase the number of transistors through which the selected signal must pass.

The inputs 104, 106 of the binary selection tree 102 are coupled to one or more signal source input circuits 110, 112, 114, 116. The signal source input circuits 110, 112, 114, 116 provide another level or dimension of selection in addition to the binary selection tree 102. Thus, the selection circuit 100 is “multi-dimensional.” Specifically, one purpose of the signal source input circuits 110, 112, 114, 116 is to each receive some of the signal sources and direct those signal sources onto the inputs 104, 106 of the binary selection tree 102. The signal sources 0-7 are received at signal source nodes (or input nodes) 109, 111, 113, 115, 117, 119, 121, 123, respectively. Each of the signal source input circuits 110, 112, 114, 116 includes one memory cell and a number of transistors equal to the number of inputs of the binary selection tree 102. Specifically, the signal source input circuit 110 includes one memory cell 118 and two transistors M54, M56, the signal source input circuit 112 includes one memory cell 120 and two transistors M58, M60, the signal source input circuit 114 includes one memory cell 122 and two transistors M62, M64, and the signal source input circuit 116 includes one memory cell 124 and two transistors M66, M68.

Each of the memory cells 118, 120, 122, 124 has its Q output coupled to the gates of its respective transistors. The source and drain connections of transistors M54, M56, M58, M60, M62, M64, M66, M68 may be reversed in accordance with the present invention. By way of example, transistors M50-M68 may be n-channel transistors as shown, but it should be well understood that transistors M50-M68 may alternatively be p-channel transistors in accordance with the present invention.

The signal source nodes 109, 111, 113, 115, 117, 119, 121, 123, are coupled to transistors M54, M56, M58, M60, M62, M64, M66, M68, respectively, and thus, each of the transistors in each signal source input circuit receives one of the signals sources. For example, in the signal source input circuit 110, signal source node 109 and transistor M54 receive signal source 0 and signal source node 111 and transistor M56 receive signal source 1. In the signal source input circuit 112, signal source node 113 and transistor M58 receive signal source 2 and signal source node 115 and transistor M60 receive signal source 3. Therefore, the several signal source input circuits 110, 112, 114, 116 are coupled to the two inputs 104, 106 of the binary selection tree 102. Each signal source input circuit 110, 112, 114, 116 includes two signal source nodes and is configured to couple its signal source nodes to a different one of the inputs 104, 106 of the binary selection tree 102. Taking signal source input circuit 110 as an example, the signal source nodes 109, 111 are coupled to the inputs 106, 104 of the binary selection tree 102 via transistors M54, M56, respectively.

During operation, memory cell 108 is programmed to turn on either transistor M50 or M52, but both transistors will not be turned on at the same time due to the outputs Q and Q_B being complimentary. Assuming that memory cell 108 is programmed so that its Q output is “1”, transistor M50 will be turned on and transistor M52 will be turned off. This means that whatever signal source gets coupled to input 104 will be coupled to input 22 of the configurable functional block 20, and signal sources that get coupled to input 106 will not get coupled to input 22.

Only one of the memory cells 118, 120, 122, 124 is programmed to have a “1” on its Q output. The other memory cells are programmed to have a “0” on their Q outputs. For example, suppose that signal source 1 is the selected signal source. When the Q output of memory cell 118 is “1”, both transistors M54 and M56 turn on. This means that signal source 0 gets coupled to input 106 and signal source 1 gets coupled to input 104. Because transistor M50 is also turned on, signal source 1 gets coupled to input 22, and because transistor M52 is turned off, signal source 0 does not get coupled to input 22. Furthermore, because memory cells 120, 122, 124 all have a “0” on their Q outputs, none of transistors M58, M60, M62, M64, M66, M68 are turned on. This means that none of signal sources 2-7 get coupled to either input 104 or 106. In this way, a single signal source gets coupled to input 22 of the configurable functional block 20.

As another example, suppose that signal source 6 is the selected signal source. Memory cell 108 is programmed so that its Q_B output is “1”, which in turn, turns on transistor M52 and turns off transistor M50. Then, memory cell 124 is programmed so that its Q output is “1”, which turns on both of transistors M66 and M68. This couples signal source 6 to input 106 and signal source 7 to input 104. Because transistor M52 is turned on and transistor M50 is turned off, only signal source 6 gets coupled to input 22. Furthermore, because memory cells 118, 120, 122 all have a “0” on their Q outputs, none of signal sources 1-5 get coupled to either input 104 or 106.

In order to illustrate the advantages of the selection circuit 100, it is useful to compare it with the selection circuit 16 of FIG. 1 and the selection circuit 18 of FIG. 2. Specifically, the particular selection circuit 100 shown in FIG. 4 is capable of selecting from among eight signal sources 0-7, as is the selection circuit 18 of FIG. 2. Although the selection circuit 100 uses two more memory cells than the selection circuit 18, a selected signal source must pass through only two transistors in the selection circuit 100 as opposed to three transistors in the selection circuit 18. Thus, the selection circuit 100 is an improvement over the selection circuit 18 in terms of the number of transistors through which a selected signal must pass. Furthermore, the selection circuit 100 is an improvement over the selection circuit 16 of FIG. 1 in terms of the number of memory cells used. Specifically, in order to support eight signal sources, the selection circuit 16 requires eight memory cells. In contrast, the selection circuit 100 supports eight signal sources with only five memory cells. One trade off, however, is that a selected signal passes through two transistors in the selection circuit 100 versus only one transistor in the selection circuit 16.

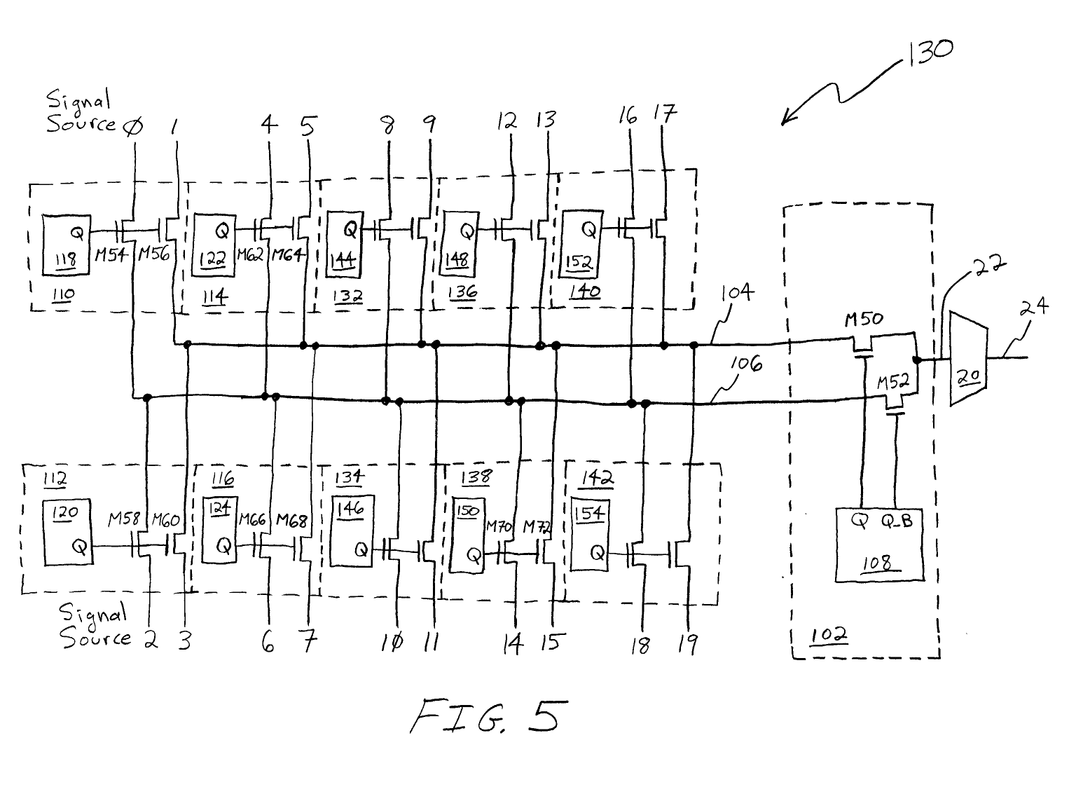

It should be understood that there is no limit to the number of signal source input circuits that may be used with the selection circuit 100 of the present invention and that virtually any number of signal source input circuits may be used in accordance with the present invention. For example, FIG. 5 illustrates a selection circuit 130 in accordance with the present invention. The selection circuit 130 is substantially the same as the selection circuit 100 except that additional signal source input circuits 132, 134, 136, 138, 140, 142 have been added. The additional signal source input circuits 132, 134, 136, 138, 140, 142 support additional signal sources 8-19 so that a total of twenty signal sources are supported by the selection circuit 130.

The operation of the selection circuit 130 is substantially the same as the selection circuit 100. For example, suppose that signal source 14 is the selected signal source. Memory cell 108 is programmed so that its Q_B output is “1”, which in turn, turns on transistor M52 and turns off transistor M50. Then, memory cell 150 is programmed so that its Q output is “1”, which turns on both of transistors M70 and M72. This couples signal source 14 to input 106 and signal source 15 to input 104. Because transistor M52 is turned on and transistor M50 is turned off, only signal source 14 gets coupled to input 22. Furthermore, because memory cells 118, 120, 122, 124, 144, 146, 148, 152, 154 all have a “0” on their Q outputs, none of signal sources 1-13 and 16-19 get coupled to either input 104 or 106.

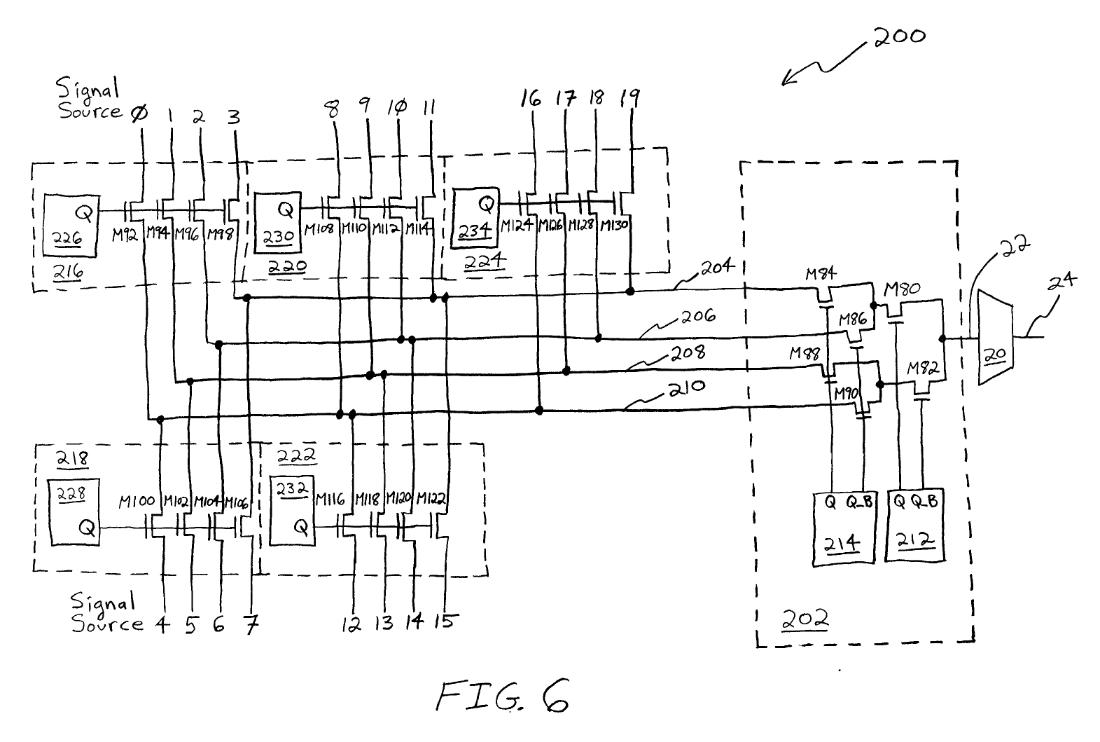

It was mentioned above that the signal source selection circuit of the present invention may use a binary selection tree having any number of stages in accordance with the present invention. To illustrate this, reference is made to FIG. 6 which illustrates a selection circuit 200 in accordance with the present invention. The selection circuit 200 uses a two stage binary selection tree 202 to connect to the configurable functional block 20. Specifically, the output of the binary selection tree 202 is connected to the input 22 of the configurable functional block 20. It should be understood that the configurable functional block 20 is not part of the selection circuit 200, but rather, the selection circuit 200 is coupled to the configurable functional block 20. Furthermore, the binary selection tree 202 may also be referred to as an output circuit 202. According to equation (1) above, the binary selection tree 202 has four inputs 204, 206, 208, 210 (or intermediate nodes 204, 206, 208, 210) and uses two memory cells 212, 214. The Q output of memory cell 212 is coupled to the gate of transistor M80, and the Q_B output of memory cell 212 is coupled to the gate of transistor M82. Similarly, the Q output of memory cell 214 is coupled to the gates of transistors M84, M88, and the Q_B output of memory cell 214 is coupled to the gates of transistors M86, M90.

The inputs 204, 206, 208, 210 of the binary selection tree 202 are coupled to signal source input circuits 216, 218, 220, 222, 224. Although five signal source input circuits 216, 218, 220, 222, 224 are shown, it should be understood that virtually any number of signal source input circuits may be used in accordance with the present invention. Using additional signal source input circuits will increase the number of signal sources supported, and using fewer signal source input circuits will decrease the number of signal sources supported.

The purpose of the signal source input circuits 216, 218, 220, 222, 224 is to each receive some of the signal sources and direct or couple those signal sources onto the inputs 204, 206, 208, 210 of the binary selection tree 202. Each of the signal source input circuits 216, 218, 220, 222, 224 includes one memory cell and a number of transistors equal to the number of inputs of the binary selection tree 202, which in this scenario is four. Specifically, the signal source input circuit 216 includes one memory cell 226 and four transistors M92, M94, M96, M98, the signal source input circuit 218 includes one memory cell 228 and four transistors M100, M102, M104, M106, the signal source input circuit 220 includes one memory cell 230 and four transistors M108, M110, M112, M114, the signal source input circuit 222 includes one memory cell 232 and four transistors M116, M118, M120, M122, and the signal source input circuit 224 includes one memory cell 234 and four transistors M124, M126, M128, M130. Each of the transistors in each signal source input circuit receives one of the signals sources. For example, in the signal source input circuit 216, transistor M92 receives signal source 0, transistor M94 receives signal source 1, transistor M96 receives signal source 2, and transistor M98 receives signal source 3. It is assumed herein that transistors M80-M130 are n-channel transistors, but it should be well understood that they may be p-channel transistors in accordance with the present invention.

During operation, the binary selection tree 202 is used to select one of the inputs 204, 206, 208, 210. Then the memory cell of the signal source input circuit that includes the selected signal source is programmed to have a “1” on its Q output while the memory cells of all of the other signal source input circuits are programmed to have a “0” on their Q outputs. This allows only one of the signal sources to be coupled to the input 22 of the configurable functional block 20.

For example, suppose that signal source 9 is the selected signal source. Memory cell 212 is programmed so that its Q_B output is “1”, which turns on transistor M82 and turns off transistor M80. Memory cell 214 is programmed so that its Q output is “1”, which turns on transistor M88 and turns off transistor M90. Then, memory cell 230 is programmed so that its Q output is “1”, which turns on all of transistors M108, M110, M112, M114. This couples signal source 8 to input 210, signal source 9 to input 208, signal source 10 to input 206, and signal source 11 to input 204. Because transistors M88 and M82 are turned on, signal source 9 gets coupled to input 22. Signal sources 8, 10, 11 do not get coupled to input 22 because transistors M80 and M90 are turned off. Furthermore, because memory cells 226, 228, 232, 234 all have a “0” on their Q outputs, none of signal sources 1-7 and 12-19 get coupled to any of inputs 204, 206, 208, 210.

In order to further illustrate the advantages of the present invention, it is useful to compare the selection circuit 200 with the selection circuit 16 of FIG. 1 and the selection circuit 18 of FIG. 2. Specifically, the particular selection circuit 200 shown in FIG. 6 is capable of selecting from among twenty signal sources. In order to support twenty signal sources, the selection circuit 16 of FIG. 1 requires twenty memory cells. In contrast, the selection circuit 200 supports twenty signal sources with only seven memory cells. One trade off, however, is that a selected signal passes through only one transistor in the selection circuit 16 versus three transistors in the selection circuit 200. The selected signal source passes through three transistors in the selection circuit 200 because the binary selection tree 202 is a two stage tree and the selected signal source input circuit adds one more transistor.

In order for the selection circuit 18 of FIG. 2 to support twenty signal sources, it would have to be modified to a five stage tree. This is because a four stage tree would yield only 2⁴ or 16 inputs and a five stage tree yields 2⁵ or 32 inputs. A five stage binary tree requires that the selected signal source pass through five transistors. In contrast, the selection circuit 200 supports twenty signal sources with the selected signal source passing through only three transistors. One trade off, however, is that a five stage binary tree uses only five memory cells whereas the selection circuit 200 uses seven memory cells. Thus, the selection circuit 200 is an improvement over the selection circuit 18 in terms of the number of transistors through which a selected signal must pass, and the selection circuit 200 is an improvement over the selection circuit 16 in terms of the number of memory cells used.

With respect to the loading of non-selected signal sources for the selection circuit 200, sixteen of the twenty signal sources, or 80% of the signal sources, will be loaded by only one turned-off transistor. This is because four of the five memory cells 226, 228, 230, 232, 234 will be programmed to have a “0” at their Q outputs which will turn off sixteen of the twenty connection transistors M92-M130. Furthermore, because only the Q outputs and not the Q_B outputs of the memory cells 226, 228, 230, 232, 234 are utilized, the determination of loading with respect to turned-off transistors is simplified and reduced. Thus, 16/20 or 80% of the signal sources will each be loaded by only one turned-off transistor. The remaining four signal sources, or 20%, are associated with a memory cell that has its Q output programmed to a “1” such that the connection transistors of that particular signal source input circuit are all turned on. Of these four signal sources, one is the selected signal source and three are non-selected signal sources. The selected signal source is loaded by three turned-on transistors. One of the three non-selected signal sources is loaded by two turned-on transistors, and the remaining two of the non-selected signal sources are each loaded by one turned-on transistor. Furthermore, the three non-selected signal sources are loaded by turned-off transistors in the binary selection tree 202.

To summarize thus far, a signal source selection circuit in accordance with the present invention uses a binary selection tree having L stages (or L memory cells). According to equation (1) above, the number of inputs to such a selection tree is equal to K=2^{L}. Then J signal source input circuits are established which each include one memory cell controlling a number of transistors equal to the number of inputs of the binary selection tree, i.e., K. Thus, the total number of memory cells used is equal to J+L, and the total number of signal sources supported is equal to (K*J). Again, the variables are defined as follows:

L=number of stages (memory cells) in binary selection tree;

K=2^{L}=number of inputs to the binary selection tree, the number of transistors in each signal source input circuit, and the number of signal sources per signal source input circuit;

J=number of signal source input circuits or groups of signal sources;

J+L=total number of memory cells; and

K*J=total number of signal sources supported.

Therefore, the present invention provides an apparatus and method for selecting a signal source from among several signal sources (or input signals). The selection is made by arranging the several input signals into J number of groups of input signals. This arrangement may be made by establishing J number of signal source input circuits. Each such signal source input circuit will normally include K number of input nodes and be coupled to K number of intermediate nodes. Then one group of the J number of groups of input signals is selected. This specific group of signals may be selected by programming a memory cell included in each of the signal source input circuits. Only one of the signal source input circuits (or groups) is normally selected at a time. Then the input signals in the selected group are each coupled to a different one of the inputs of the binary selection tree. This coupling may be provided by turning on transistors included in the signal source input circuit for the selected one group of the J number of groups of input signals. Each one of these transistors couples a different one of the K number of input nodes to a different one of the K number of intermediate nodes. The binary selection tree is then programmed to select one of the intermediate nodes, i.e., one of its inputs. In other words, once a signal source input circuit is selected, the binary selection tree is used to select one of the signal sources coupled to the selected signal source input circuit.

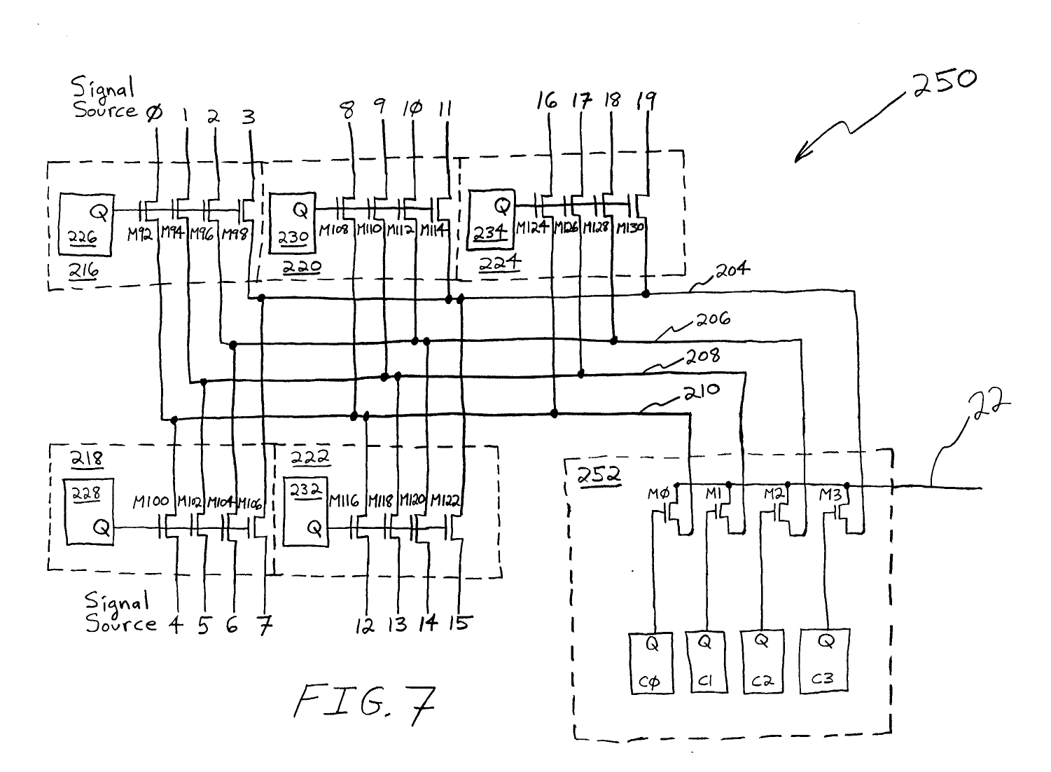

Referring to FIG. 7, there is illustrated yet another selection circuit 250 in accordance with the present invention. The selection circuit 250 further illustrates the multidimensional aspect of the present invention. Specifically, the selection circuit 250 is similar to the selection circuit 200 of FIG. 6 except that the binary selection tree 202 has been replaced with an output circuit 252 similar to the selection circuit 16 shown in FIG. 1. The output circuit 252 is used to couple one of the intermediate nodes 204, 206, 208, 210 to node 22. Specifically, during use one of the memory cells C0-C3 is programmed to have a “1” on its Q output and the remainder of the memory cells C0-C3 are programmed to have a “0” on their Q outputs. This turns on only one of the corresponding transistors M0-M3. This way, only one of the intermediate nodes 204, 206, 208, 210 is coupled to node 22.

An advantage of the selection circuit 250 is that the signals on the intermediate nodes 204, 206, 208, 210 need to pass through only one transistor to reach node 22, whereas those signals need to pass through two transistors in the binary selection tree 202 shown in FIG. 6. One disadvantage of the selection circuit 250, however, is that the output circuit 252 uses four memory cells C0-C3, whereas the binary selection tree 202 shown in FIG. 6 uses only two memory cells 212-214.

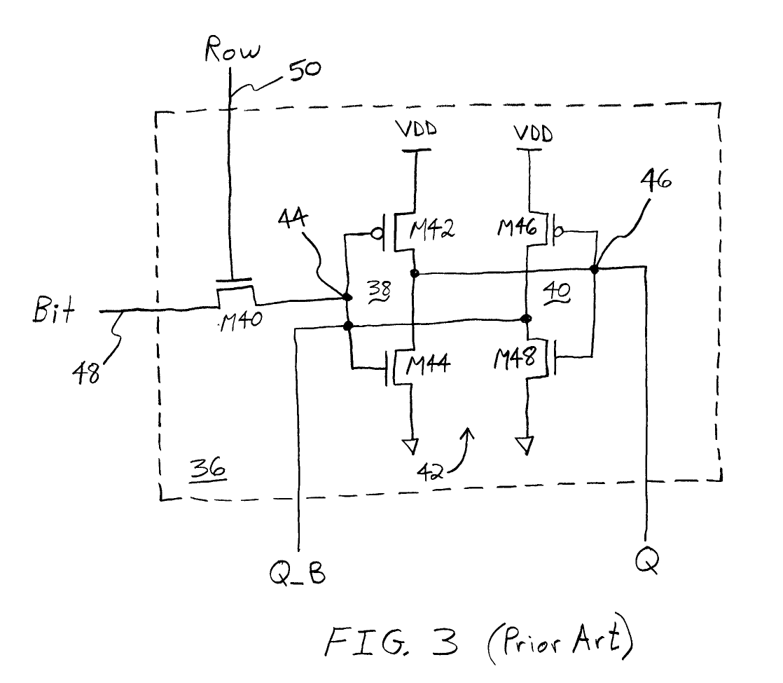

Many different types of memory cells may be used for the memory cells of the selection circuits 100, 130, 200 and 250 described above (i.e., the memory cells 108, 118-124, 144-154, 212-214, 226-234, C0-C3). For example, the conventional CMOS static random access memory (SRAM) cell 36 shown in FIG. 3 above may be used for one or more or all of these memory cells, with the Q and Q_B outputs being used where appropriate. The memory cells of the selection circuits 100, 130, 200 and 250 may also utilize the memory and storage cell scheme described in copending U.S. application Ser. No. ______, filed Jan. 15, 1999, entitled “STORAGE CELLS UTILIZING REDUCED PASS GATE VOLTAGES FOR READ AND WRITE OPERATIONS”, invented by Eddy C. Huang, and commonly assigned herewith, the full disclosure of which is incorporated herein by reference.

Furthermore, it should be understood that the memory cells of the selection circuits 100, 130, 200 and 250 described above (i.e., the memory cells 108, 118-124, 144-154, 212-214, 226-234, C0-C3) may be replaced by some other means of turning the respective connection transistors on and off. For example, these memory cells could be replaced by a binary decoder circuit or the like which could be either internal or external to the circuits 100, 130, 200 and 250. This way some or all of the programmable memory cells 108, 118-124, 144154, 212-214, 226-234, C0-C3 would not be needed.

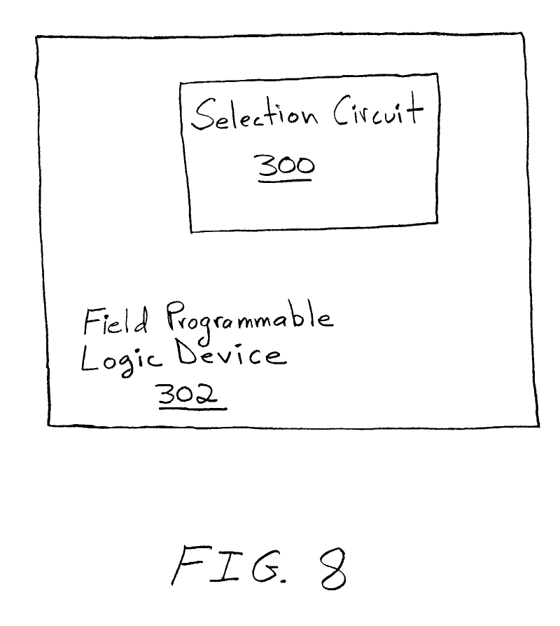

FIG. 8 illustrates the use, in accordance with the present invention, of a selection circuit 300 of the present invention being used in a field programmable logic device 302. The selection circuit 300 may comprise any one of the selection circuits 100, 130, 200 and 250 described above. It should be well understood, however, that the selection circuits of the present invention are not limited to use within field programmable logic devices. The selection circuits of the present invention, such as the selection circuits 100, 130, 200 and 250, have numerous other applications and uses, such as for example, any use or application where a selection needs to be made among a number of input signals. Moreover, it should be understood that the selection circuits of the present invention, such as the selection circuits 100, 130, 200 and 250 described above, do not have to be used for providing an input to a configurable functional block, such as the configurable functional block 20 shown in the figures.

It should be understood that various alternatives to the embodiments of the invention described herein may be employed in practicing the invention. It is intended that the following claims define the scope of the invention and that structures and methods within the scope of these claims and their equivalents be covered thereby.

What is claimed is:

1. An apparatus including a selection circuit, the selection circuit comprising:
a binary selection tree having an output and K number of inputs; and
a plurality of signal source input circuits coupled to the K number of inputs of the binary selection tree, each signal source input circuit including K number of signal source nodes and being configured to couple each of the K number of signal source nodes to a different one of the K number of inputs of the binary selection tree.

2. An apparatus in accordance with claim 1, wherein each signal source input circuit further comprises:
K number of transistors arranged so that each transistor couples a different one of the K number of signal source nodes to a different one of the K number of inputs of the binary selection tree.

3. An apparatus in accordance with claim 2, wherein each signal source input circuit further comprises:
a memory cell having an output that is coupled to a gate of each of the K number of transistors.

4. An apparatus in accordance with claim 1, further comprising:
a configurable functional block coupled to the output of the binary selection tree.

5. An apparatus in accordance with claim 1, wherein the apparatus comprises a field programmable logic device.

6. A selection circuit, comprising:
an output node;
K number of intermediate nodes;
an output circuit coupled to the output node and the K number of intermediate nodes, the output circuit configured to selectively couple the output node to a different one of the K number of intermediate nodes; and
a plurality of signal source input circuits coupled to the K number of intermediate nodes, each signal source input circuit including K number of input nodes and being configured to couple each of the K number of input nodes to a different one of the K number of intermediate nodes.

7. A selection circuit in accordance with claim 6, wherein the output circuit comprises:
K number of output transistors, each one of the K number of output transistors coupled between the output node and a different one of the K number of intermediate nodes.

8. A selection circuit in accordance with claim 7, wherein the output circuit further comprises:
K number of output memory cells that each have an output coupled to a gate of a different one of the K number of output transistors.

9. A selection circuit in accordance with claim 6, wherein the output circuit comprises:
a binary selection tree having an output coupled to the output node and K number of inputs respectively coupled to the K number of intermediate nodes.

10. A selection circuit in accordance with claim 6, wherein each signal source input circuit further comprises:
K number of input transistors that are arranged so that each input transistor couples a different one of the K number of input nodes to a different one of the K number of intermediate nodes.

11. A selection circuit in accordance with claim 10, wherein each signal source input circuit further comprises:
an input memory cell having an output that is coupled to a gate of each of the K number of input transistors.

12. A selection circuit, comprising:
a binary selection tree having an output and K number of inputs; and
a plurality of signal source input circuits coupled to the K number of inputs of the binary selection tree, each signal source input circuit including:
K number of input nodes;
a memory cell; and
K number of transistors that each have a gate coupled to an output of the memory cell and that are arranged so that each transistor couples a different one of the K number of input nodes to a different one of the K number of inputs of the binary selection tree.

13. A selection circuit in accordance with claim 12, wherein the K number of transistors each have a drain/source conduction path coupled between the different one of the K number of input nodes and the different one of the K number of inputs of the binary selection tree.

14. A selection circuit in accordance with claim 12, wherein the K number of transistors comprises n-channel transistors and the output of the memory cell comprises a Q output.

15. A selection circuit in accordance with claim 12, wherein the binary selection tree comprises a one-stage binary selection tree having two inputs.

16. A selection circuit in accordance with claim 12, wherein the binary selection tree comprises a two-stage binary selection tree having four inputs.

17. A selection circuit in accordance with claim 12, wherein K is equal to two.

18. A selection circuit in accordance with claim 12, wherein K is equal to four.

19. A method of selecting from among a plurality of input signals, comprising:
arranging the plurality of input signals into J number of groups of input signals;
selecting one group from the J number of groups of input signals;
coupling each one of the input signals in the selected group to a different one of K number of intermediate nodes; and
selecting one of the K number of intermediate nodes with a binary selection tree having K number of inputs.

20. A method in accordance with claim 19, wherein the step of arranging the plurality of input signals into J number of groups of input signals comprises:
establishing J number of signal source input circuits, each signal source input circuit being coupled to the K number of intermediate nodes and including K number of input nodes.

21. A method in accordance with claim 20, wherein the step of coupling each one of the input signals in the selected group to a different one of K number of intermediate nodes comprises:
turning on K number of transistors included in the signal source input circuit for the selected one of the J number of groups of input signals, each one of the K number of transistors coupling a different one of the K number of input nodes in the signal source input circuit to a different one of the K number of intermediate nodes.

22. A method in accordance with claim 20, wherein the step of selecting one group from the J number of groups of input signals comprises:
programming a memory cell included in the signal source input circuit for the selected one of the J number of groups of input signals.

23. A method in accordance with claim 20, wherein the step of selecting one of the K number of intermediate nodes with a binary selection tree having K number of inputs comprises:
coupling the binary selection tree to the K number of intermediate nodes.
